(19) United States
(12) Patent Application Publication
(10) Pub. No.: US 2021/0087673 A1
(43) Pub. Date: Mar. 25, 2021

(54) SPUTTERING TARGET

(71) Applicants: TANAKA KIKINZOKU KOGYO K.K., Tokyo (JP); TOHOKU UNIVERSITY, Sendai-shi, Miyagi (JP)

(72) Inventors: Kim Kong THAM, Tsukuba-shi (JP); Ryousuke KUSHIBIKI, Tsukuba-shi (JP); Tomonari KAMADA, Tsukuba-shi (JP); Masahiro AONO, Tsukuba-shi (JP); Takeshi ISHIBASHI, Tsukuba-shi (JP); Takeshi NUMAZAKI, Tsukuba-shi (JP); Shin SAITO, Sendai-shi (JP)

(73) Assignees: TANAKA KIKINZOKU KOGYO K.K., Tokyo (JP); TOHOKU UNIVERSITY, Sendai-shi, Miyagi (JP)

(21) Appl. No.: 17/041,315

(22) PCT Filed: Jan. 17, 2019
(86) PCT No.: PCT/JP2019/001319

§ 371 Date: Sep. 24, 2020

(30) Foreign Application Priority Data
Mar. 30, 2018 (JP) 2018-069386

(51) Int. Cl. C23C 14/34; C23C 14/14; G11B 5/851; C23C 14/08

(52) U.S. Cl. CPC C23C 14/3414; C23C 14/08; G11B 5/851; C23C 14/14

(57) ABSTRACT

A sputtering target that can be used for forming a buffer layer that enables magnetic crystal grains in a magnetic recording layer granular film to be well separated when the magnetic recording layer granular film is stacked above a Ru underlayer. The target contains a metal and an oxide, wherein: the contained metal becomes a nonmagnetic metal including an hcp structure if the entirety of the contained metal is made into a single metal, the lattice constant “a” of the hcp structure included in the nonmagnetic metal being 2.59 Å or more and 2.72 Å or less; the contained metal includes 4 at % or more of metallic Ru relative to the whole amount of the contained metal; and the sputtering target contains 20 vol % or more and 50 vol % or less of the oxide relative to the entire sputtering target, the melting point of the contained oxide being 1700° C. or more.

### TECHNICAL FIELD

The present invention relates to a sputtering target, and in particular, to a sputtering target that can be suitably used for forming a buffer layer between a substrate and a magnetic recording layer. In the present application, the buffer layer is a layer provided between a Ru underlayer and a magnetic recording layer in a magnetic recording medium.

### BACKGROUND ART

In order to increase the recording density of a granular film used as a magnetic recording medium of a hard disk, it is essential to reduce the thickness of the underlayer and increase the coercive force of the granular film.

In order to increase the coercive force of the granular film, the magnetocrystalline anisotropy constant Kᵤ of magnetic crystal grains in the granular film needs to be increased. As a grain boundary material in granular films containing CoPt alloy crystal grains as magnetic crystal grains, various oxides have been investigated to date, and as a result, it has been found that the containing of B₂O₃ having a low melting point of 450° C. as a grain boundary material is effective for increasing the coercive force of granular films (Non-Patent Document 1).

However, when a granular film is formed by stacking CoPt—B₂O₃ on a Ru underlayer, it has been found that the isolation of adjacent CoPt magnetic crystal grains due to B₂O₃ in the formed granular film is inadequate in the early stage of forming CoPt magnetic crystal grains, and the adjacent CoPt magnetic crystal grains are magnetically coupled to each other, thereby decreasing the coercive force (Non-Patent Document 2).

In response to this, the present inventors have proposed to provide a buffer layer between a Ru underlayer and a magnetic recording layer in Non-Patent Literature 3. However, a composition and the like suitable for the buffer layer of the magnetic recording medium have not been clarified.

### CITATION LIST

### Non-Patent Literature

Non-Patent Literature 1: K. K. Tham et al., Japanese Journal of Applied Physics, 55, 07MC06 (2016)
Non-Patent Literature 2: R. Kushibiki et al., IEEE Transactions on Magnetics, VOL. 53, No. 11, 3200604, November 2017
Non-Patent Literature 3: K. K. Tham et al., IEEE Transactions on Magnetics, VOL. 54, No. 2, 3200404, February 2018

### SUMMARY OF INVENTION

### Technical Problem

The present invention has been made under such circumstances, and an object of the present invention is to provide a sputtering target that can be used for forming a buffer layer that enables magnetic crystal grains in a magnetic recording layer granular film to be well separated each other when the magnetic recording layer granular film is stacked above a Ru underlayer.

### Solution to Problem

The present invention solves the above-mentioned problem by means of the following sputtering target.

That is, the sputtering target according to the present invention is a sputtering target containing a metal and an oxide, wherein: the contained metal becomes a nonmagnetic metal including an hcp structure if the entirety of the contained metal is made into a single metal, the lattice constant “a” of the hcp structure included in the nonmagnetic metal being 2.59 Å or more and 2.72 Å or less; the contained metal includes 4 at % or more of metallic Ru relative to the whole amount of the contained metal; and the sputtering target contains 20 vol % or more and 50 vol % or less of the oxide relative to the entire sputtering target, the melting point of the contained oxide being 1700° C. or more.

Here, when the sputtering target contains one kind of metal, “if the entirety of the contained metal is made into a single metal”, the single metal refers to the one kind of metal, and when the sputtering target contains two or more kinds of metal, “if the entirety of the contained metal is made into a single metal”, the single metal refers to an alloy composed of the two or more kinds of metal. Hereinafter, similar descriptions elsewhere in the present application shall be construed in the same manner.

The lattice constant “a” refers to the closest interatomic distance in the hcp structure as measured by the X-ray diffraction method, and shall be interpreted in the same manner when it is described elsewhere in the present application.

When the contained oxide consists of plural kinds of oxides, the “melting point of the contained oxide” is calculated by a weighted average of the content ratio (volume ratio to the total of the contained oxides) of each of the oxides with respect to the melting point of each kind of the contained oxides. Hereinafter, similar descriptions elsewhere in the present application shall be construed in the same manner.

Further, at least one metal selected from the group consisting of Nb, Ta, W, Ti, Pt, Mo, V, Mn, Fe, and Ni may be contained in the sputtering target in a total amount of more than 0 at % and 31 at % or less relative to the whole amount of the metal contained in the sputtering target.

At least one metal selected from the group consisting of Co and Cr may be contained in the sputtering target in a total amount of more than 0 at % and less than 55 at % relative to the whole amount of the metal contained in the sputtering target.

Two or more metals selected from the group consisting of metallic Co, metallic Cr, and metallic Pt may be contained, and in this case, the metallic Ru may be contained in an amount of 20 at % or more and less than 100 at %, the metallic Co may be contained in an amount of 0 at % or more and less than 55 at %, the metallic Cr may be contained in an amount of 0 at % or more and less than 55 at %, and the metallic Pt may be contained in an amount of 0 at % or more and 31 at % or less relative to the whole amount of the metal contained in the sputtering target.

The hardness of the sputtering target is preferably 920 or more by Vickers hardness HV10.

The oxide may be an oxide of at least one element selected from the group consisting of Si, Ta, Co, Mn, Ti, Cr, Mg, Al, Y, Zr, and Hf.

The sputtering target can be suitably used for forming a buffer layer between a Ru underlayer and a magnetic recording layer.

### Advantageous Effects of Invention

According to the present invention, it is possible to provide a sputtering target that can be used for forming a buffer layer that enables magnetic crystal grains in a magnetic recording layer granular film to be well separated each other when the magnetic recording layer granular film is stacked above a Ru underlayer.

### BRIEF DESCRIPTION OF DRAWINGS

FIG. 1(A) is a STEM (scanning transmission electron microscope) photograph of a perpendicular cross section of the magnetic recording medium 10 of Example 1, FIG. 1(B) is an image showing a result of Cr analysis of energy dispersive X-ray analysis by STEM (scanning transmission electron microscope), and FIG. 1(C) is an image showing a result of Ru analysis of energy dispersive X-ray analysis by STEM (scanning transmission electron microscope).

FIG. 2(A) is a TEM (transmission electron microscope) photograph of the horizontal cross section of a magnetic recording layer granular film 16 of a magnetic recording medium of Example 1, and FIG. 2(B) is a TEM (transmission electron microscope) photograph of the horizontal cross section of a magnetic recording layer granular film 56 of a magnetic recording medium of Comparative Example 1.

FIG. 3(A) is a schematic vertical cross-sectional diagram of a magnetic recording medium 10 in which a buffer layer 14 is formed on a Ru underlayer 12 and a magnetic recording layer granular film 16 is formed on the formed buffer layer 14, and FIG. 3(B) is a schematic vertical cross-sectional diagram of a magnetic recording medium 50 in which a magnetic recording layer granular film 56 is directly formed on a Ru underlayer 52 without providing a buffer layer 14.

FIG. 4 is a graph in which the horizontal axis shows the melting point of the oxide of a buffer layer and the vertical axis shows the coercive force Hc.

FIG. 5 is a graph in which the horizontal axis shows the melting point of the oxide of a buffer layer and the vertical axis shows the thickness of the buffer layer when the coercive force Hc of a magnetic recording layer granular film reaches its peak value.

FIG. 6 is a graph in which the horizontal axis shows the oxide content of a buffer layer and the vertical axis shows the thickness of the buffer layer when the coercive force Hc of a magnetic recording layer granular film reaches its peak value.

### DESCRIPTION OF EMBODIMENTS

The sputtering target according to the embodiment of the present invention is a sputtering target containing a metal and an oxide, and if the entirety of the contained metal is made into a single metal, the contained metal becomes a nonmagnetic metal including an hcp structure, the lattice constant “a” of the hcp structure included in the nonmagnetic metal being 2.59 Å or more and 2.72 Å or less, and the contained metal includes 4 at % or more of metallic Ru relative to the whole amount of the contained metal, and the sputtering target contains 20 vol % or more and 50 vol % or less of the oxide relative to the entire sputtering target, the melting point of the contained oxide being 1700° C. or more, and can be suitably used for forming a buffer layer between a Ru underlayer and a magnetic recording layer granular film in a magnetic recording medium.

When a granular film serving as a magnetic recording layer is formed on the buffer layer formed on a Ru underlayer by using the sputtering target according to the present embodiment, magnetic crystal grains in the formed granular film are well separated by an oxide phase, and the coercive force of the resulting magnetic recording layer can be improved.

In the present application, a sputtering target for a magnetic recording medium may be simply referred to as a sputtering target or a target. In the present application, the metallic Ru may be simply referred to as Ru, the metallic Co may be simply referred to as Co, the metallic Pt may be simply referred to as Pt, and the metallic Cr may be simply referred to as Cr. Other metal elements may be described in the same manner.

### (1) Components of the Target

As described above, the sputtering target according to the present embodiment is a sputtering target containing a metal and an oxide.

The metal contained in the sputtering target according to the present embodiment becomes a nonmagnetic metal including an hcp structure if the entirety of the contained metal is made into a single metal, and the lattice constant “a” of the hcp structure included in the nonmagnetic metal is 2.59 Å or more and 2.72 Å or less. The contained metal includes 4 at % or more of metallic Ru relative to the whole amount of the contained metal. The metal contained in the sputtering target according to the present embodiment will be described in detail in “(3) Determination of the metal component based on expression mechanisms of action effects” described later.

The oxide contained in the sputtering target according to the present embodiment is an oxide having a melting point of 1700° C. or more, and the content of the oxide is 20 vol % or more and 50 vol % or less relative to the entire sputtering target. The melting point, the content, and specific examples of the oxide contained in the sputtering target according to the present embodiment will be described in detail in “(4) Melting point of the oxide”, “(5) Content of the oxide”, and “(6) Specific Examples of the oxide” described later.

When a granular film serving as a magnetic recording layer is formed on the buffer layer which is formed on a Ru underlayer by the sputtering target according to the present embodiment containing the aforementioned metal and oxide, a magnetic recording layer having a large coercive force Hc is obtained. This is demonstrated in the Examples described below.

### (2) Action Effects and Expression Mechanisms Thereof

The action effects and the expression mechanisms of the action effects of the buffer layer formed by using the sputtering target according to the present embodiment will be described, and in this section, a magnetic recording medium 10 of Example 1 and a magnetic recording medium 50 of Comparative Example 1, which will be described below, will be taken up. The sputtering target used for the preparation of a buffer layer in Example 1 has a composition of Ru₅₀Co₂₅Cr₂₅-30 vol % TiO₂, which is included in the sputtering target according to the present embodiment. The reason why the sputtering target having the above composition of Example 1 is included in the sputtering target according to the present embodiment is that, if Ru₅₀Co₂₅Cr₂₅, which is a metal component of the above composition, is made into a single metal, the single metal becomes a nonmagnetic metal including an hcp structure, the lattice constant “a” of the hcp structure included in the nonmagnetic metal being 2.63 Å (i.e., the lattice constant “a” is within a range of 2.59 Å or more and 2.72 Å or less); the contained metal contains 4 at % or more of a metallic Ru relative to the whole amount of the contained metal; and the sputtering target contains an oxide TiO₂ of 30 vol % (i.e., the content is 20 vol % or more and 50 vol % or less), the melting point of TiO₂ being 1857° C. (i.e., 1700° C. or more).

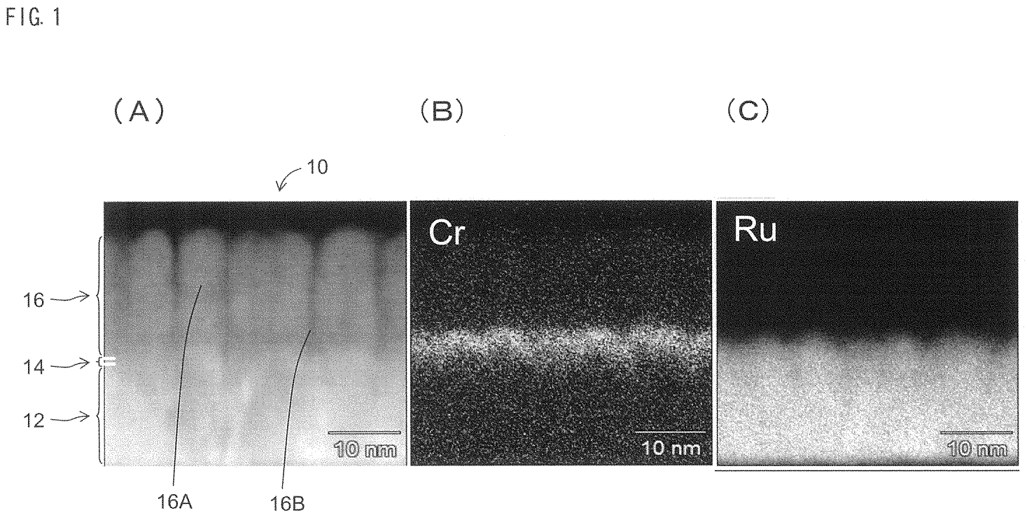

FIGS. 1(A) to (C) are figures showing the results of measurements by STEM (scanning transmission electron microscope) on the magnetic recording medium 10 of Example 1. FIG. 1(A) is a STEM (scanning transmission electron microscope) photograph of a perpendicular cross section of the magnetic recording medium 10 of Example 1. FIGS. 1(B) and (C) are images showing analysis results of energy dispersive X-ray analysis by STEM (scanning transmission electron microscope); FIG. 1(B) is an analysis result of Cr, and FIG. 1(C) is an analysis result of Ru.

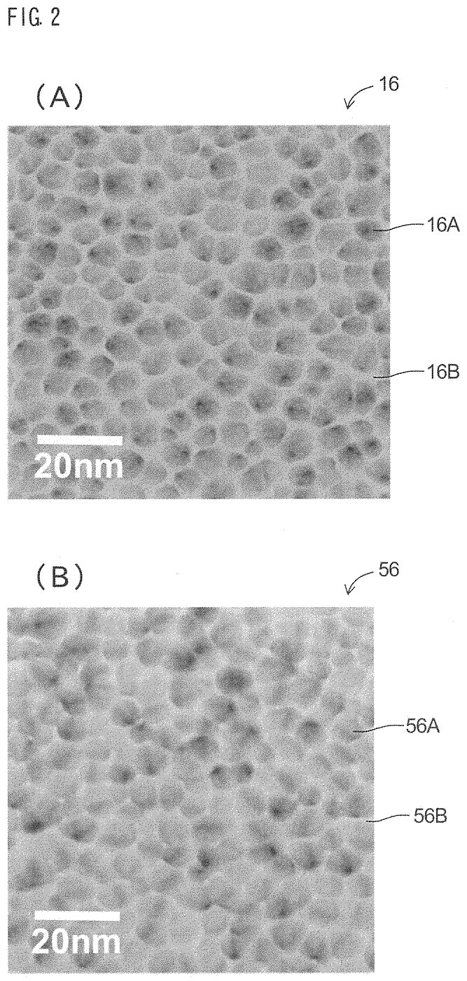

FIGS. 2(A) and (B) are TEM (Transmission Electron Microscope) photographs (TEM photographs of the horizontal cross-section of a magnetic recording layer granular film) for showing the effects of the buffer layer formed by using the sputtering target according to the present embodiment. FIG. 2(A) is a TEM photograph (TEM photograph of the magnetic recording medium of Example 1, the TEM photograph being the horizontal cross-section of the portion where the distance from the Ru underlayer is 40 Å) of the horizontal cross-section of the magnetic recording layer granular film Co₈₀Pt₂₀-30 vol % B₂O₃ portion of the magnetic recording medium in which the buffer layer is formed on a Ru underlayer by using the sputtering target (Ru₅₀Co₂₅Cr₂₅-30 vol % TiO₂) included in the scope of the sputtering target according to the present embodiment, and the magnetic recording layer granular film Co₈₀Pt₂₀-30 vol % B₂O₃ is formed on the formed buffer layer. FIG. 2(B) is a TEM photograph (TEM photograph of the magnetic recording medium of Comparative Example 1, the TEM photograph being the horizontal cross-section of the portion where the distance from the Ru underlayer is 40 Å) of the horizontal cross-section of the magnetic recording layer granular film Co₈₀Pt₂₀-30 vol % B₂O₃ portion of the magnetic recording medium in which the magnetic recording layer granular film Co₈₀Pt₂₀-30 vol % B₂O₃ is formed directly on a Ru underlayer without forming a buffer layer between the Ru underlayer and the magnetic recording layer granular film.

In the magnetic recording medium 10 of Example 1, the composition of a buffer layer 14 formed on a Ru underlayer 12 is Ru₅₀Co₂₅Cr₂₅-30 vol % TiO₂, and the composition of a magnetic recording layer granular film 16 formed on the buffer layer 14 is Co₈₀Pt₂₀-30 vol % B₂O₃.

As shown in FIGS. 1(A) and 2(A), magnetic crystal grains (Co₈₀Pt₂₀ alloy grains) 16A of the magnetic recording layer granular film 16 formed on the buffer layer 14 are neatly separated by an oxide (B₂O₃) phase 16B.

In contrast, in a magnetic recording layer granular film Co₈₀Pt₂₀-30 vol % B₂O₃ of the magnetic recording medium in which the magnetic recording layer granular film Co₈₀Pt₂₀-30 vol % B₂O₃ is directly provided on a Ru underlayer without providing a buffer layer between the Ru underlayer and the magnetic recording layer granular film, as shown in FIG. 2(B), the boundaries between magnetic crystal grains (Co₈₀Pt₂₀ alloy grains) 56A of a magnetic recording layer granular film 56 are obscured and the separation by an oxide (B₂O₃) phase 56B is insufficient.

Therefore, the buffer layer 14 formed on the Ru underlayer 12 by using the sputtering target included in the present embodiment serves to satisfactorily separate the magnetic crystal grains 16A of the magnetic recording layer granular film 16 formed thereon, and reduce the magnetic interaction between the magnetic crystal grains 16A, and consequently increase the coercive force Hc of the magnetic recording layer granular film 16.

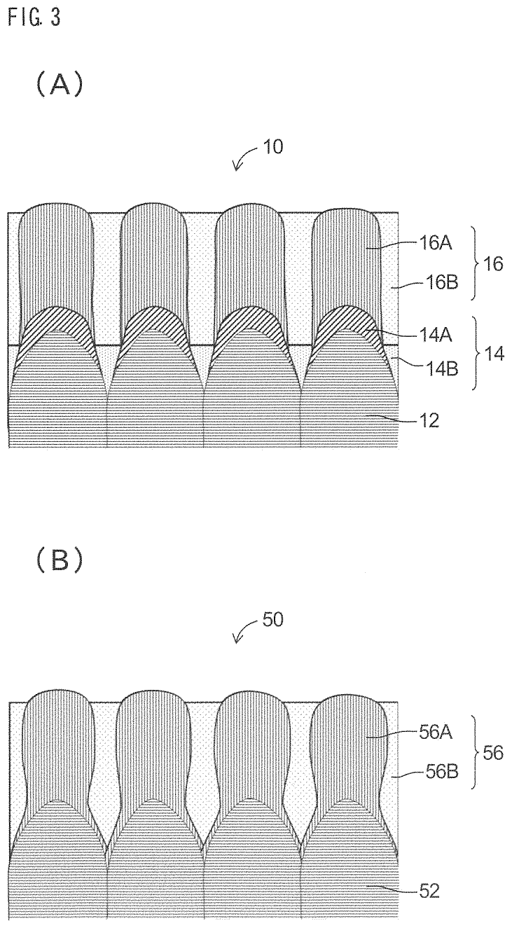

FIGS. 3(A) and 3(B) are schematic vertical cross-sectional diagrams for explaining an expression mechanism of action effects of a buffer layer formed by using the sputtering target according to the present embodiment; FIG. 3(A) is a schematic vertical cross-sectional diagram of the magnetic recording medium 10 in which a buffer layer 14 (a buffer layer formed by the sputtering target according to the present embodiment) is formed on a Ru underlayer 12 and the magnetic recording layer granular film 16 is formed on the formed buffer layer 14, and FIG. 3(B) is a schematic vertical cross-sectional diagram of the magnetic recording medium 50 in which a magnetic recording layer granular film 56 is directly formed on a Ru underlayer 52 without providing a buffer layer 14.

Hereinafter, a mechanism for expressing the action effects of the buffer layer 14 formed by using the sputtering target according to the present embodiment will be described, and this mechanism is estimated based on experimental data obtained at present. For the sake of concrete explanation, the composition of each part in FIGS. 3(A) and 3(B) is the same as the composition of the corresponding part of the magnetic recording medium of Example 1 and Comparative Example 1, respectively. That is, the composition of the buffer layer 14 in FIG. 3(A) is assumed to be Ru₅₀Co₂₅Cr₂₅-30 vol % TiO₂, and the composition of the magnetic recording layer granular film 16 and 56 in FIGS. 3(A) and 3(B) is assumed to be Co₃₀Pt₂₀-30 vol % B₂O₃. Further, FIG. 3(A) is also a diagram schematically showing the STEM photograph of FIG. 1(A), and therefore, the same reference numerals as FIG. 1(A) are assigned to corresponding parts.

First, a magnetic recording medium 50 in which a buffer layer is not provided on a Ru underlayer and a magnetic recording layer granular film is directly formed on the Ru underlayer will be described with reference to FIG. 3(B). When the magnetic recording layer granular film 56 is directly formed on the Ru underlayer 52 without providing a buffer layer on the Ru underlayer 52, the magnetic crystal grains 56A grow along the surfaces of the Ru underlayer 52 in the early stage of forming the magnetic crystal grains (Co₃₀Pt₂₀ alloy grains) 56A as shown in FIG. 3(B), so that a portion connected to the adjacent magnetic crystal grains 56A is generated in the lower portion of the magnetic crystal grains 56A (in the vicinity of the Ru underlayer 52). Therefore, when the magnetic recording layer granular film 56 is directly formed on the Ru underlayer 52, the magnetic crystal grains 56A are insufficiently separated from each other by the oxide (B₂O₃) phase 56B, and the magnetic interaction between the magnetic crystal grains 56A becomes large, and consequently the coercive force Hc of the magnetic recording layer granular film 56 of the magnetic recording medium 50 becomes small.

In contrast, as shown in FIG. 3(A), when the buffer layer 14 is first formed on the Ru underlayer 12 by using the sputtering target according to the present embodiment and the magnetic recording layer granular film 16 is formed on the buffer layer 14, magnetic crystal grains (Co₈₀Pt₂₀ alloy grains) 16A of the magnetic recording layer granular film 16 grow on the alloy (Ru₅₀Co₂₅Cr₂₅) phase 14A which is the metal component of the buffer layer 14, and the oxide (B₂O₃) phase 16B of the magnetic recording layer granular film 16 is deposited on the oxide (TiO₂) phase 14B which is the oxide component of the buffer layer 14, so that the magnetic crystal grains (Co₈₀Pt₂₀ alloy grains) 16A of the magnetic recording layer granular film 16 are well separated by the oxide (B₂O₃) phase 16B. Therefore, the magnetic interaction between the magnetic crystal grains 16A becomes small, and consequently the coercive force Hc of the magnetic recording layer granular film 16 of the magnetic recording medium 10 becomes large.

In order to explain the above mechanism in more detail, the phase structure of the buffer layer 14 is explained, and the above mechanism is further explained.

The buffer layer 14 is composed of an alloy (Ru₅₀Co₂₅Cr₂₅) phase 14A and an oxide (TiO₂) phase 14B. As shown in FIG. 3(A), the Ru₅₀Co₂₅Cr₂₅ of a metal component of the buffer layer 14 is deposited on a convex portion of the Ru underlayer 12 as the alloy (Ru₅₀Co₂₅Cr₂₅) phase 14A, and the TiO₂ of an oxide component of the buffer layer 14 is deposited on a concave portion of the Ru underlayer 12 as the oxide (TiO₂) phase 14B, as shown in FIG. 3(A). Therefore, the oxide (TiO₂) phase 14B is arranged between the convex portions of the Ru underlayer (in the concave portions of the Ru underlayer 12).

The reason why the buffer layer 14 is formed in this manner is that the concave portion of the Ru underlayer 12 is shadowed from the perspective of sputtering particles flying into the Ru underlayer 12, so that the metal is easily solidified on the convex portion of the Ru underlayer 12, and therefore, the oxide is deposited in the concave portion of the Ru underlayer 12.

When the buffer layer 14 is first formed on the Ru underlayer 12 and the magnetic recording layer granular film 16 is formed on the buffer layer 14, magnetic crystal grains (Co₈₀Pt₂₀ alloy grains) 16A having low surface-energy differences from an alloy (Ru₅₀Co₂₅Cr₂₅) phase 14A of the buffer layer 14 are formed on the alloy (Ru₅₀Co₂₅Cr₂₅) phase 14A, and the oxide (B₂O₃) phase 16B is formed on an oxide (TiO₂) phase 14B of the buffer layer 14. Therefore, as shown in FIG. 3(A), the magnetic crystal grains (Co₈₀Pt₂₀ alloy grains) 16A of the magnetic recording layer granular film 16 are well separated by the oxide (B₂O₃) phase 16B, and the magnetic interaction between the magnetic crystal grains (Co₈₀Pt₂₀ alloy grains) 16A is reduced.

Therefore, when the buffer layer 14 is first formed on the Ru underlayer 12 by using the sputtering target according to the present embodiment and the magnetic recording layer granular film 16 is formed on the buffer layer 14, the magnetic grains (Co₈₀Pt₂₀ alloy grains) 16A of the magnetic recording layer granular film 16 are well separated by the oxide (B₂O₃) phase 16B. Therefore, the magnetic interaction between the magnetic grains (Co₈₀Pt₂₀ alloy grains) 16A is reduced, and consequently the coercive force Hc of the magnetic recording layer granular film 16 of the magnetic recording medium 10 is increased.

### (3) Determination of the Metal Component Based on Expression Mechanisms of Action Effects

In view of the expression mechanisms of action effects described in (2), the metal component contained in the sputtering target according to the present embodiment is prepared so as to be a metal component having the same crystal structure as the Ru underlayer and the magnetic crystal grains of the magnetic recording layer granular film and having an intermediate lattice constant between them if the entirety of the contained metal component is made into a single metal. Specifically, the contained metal is prepared so as to be a nonmagnetic metal including an hcp structure, the lattice constant “a” of the hcp structure included in the nonmagnetic metal being 2.59 Å or more and 2.72 Å or less, if the entirety of the contained metal is made into a single metal. In addition, the contained metal is prepared so that metallic Ru is contained in an amount of 4 at % or more relative to the whole amount of the contained metal.

The above-mentioned metal contained in the sputtering target according to the present embodiment is, for example, a RuX alloy in which the content of Ru is 69 at % or more and less than 100 at % (the metal element X is at least one of Nb, Ta, W, Ti, Pt, Mo, V, Mn, Fe, and Ni, and is contained in a total amount of more than 0 at % and less than 31 at %), a RuY alloy in which the content of Ru is more than 45 at % and less than 100 at % (the metal element Y is at least one of Co and Cr, and is contained in a total amount of more than 0 at % and less than 55 at %), or a RuZ alloy in which the content of the metallic Ru is 20 at % or more and less than 100 at % (the metal element Z is two or more of Co, Cr, and Pt, and the content of Co is 0 at % or more and less than 55 at %, the content of Cr is 0 at % or more and less than 55 at %, and the content of Pt is 0 at % or more and 31 at % or less).

The sputtering target according to the present embodiment may not include the alloy listed as a specific example in the preceding paragraph in an alloy state, but may include the alloy as an aggregate of fine phases of single elements of individual metal elements satisfying the composition ratio described in the preceding paragraph.

The metal component contained in the sputtering target according to the present embodiment contains 4 at % or more of metallic Ru from the standpoint of matching the lattice constant with the Ru underlayer. In addition, from the viewpoint of matching of the lattice constant with the magnetic crystal grains of the magnetic recording layer granular film, it is preferable that a metal component of the magnetic crystal grains of the magnetic recording layer granular film is contained in the sputtering target according to the present embodiment. More specifically, when the metal components of the magnetic crystal grains of the magnetic recording layer granular film are, for example, Co and Pt, it is preferable that at least one of Co and Pt is contained in the metal component contained in the sputtering target according to the present embodiment.

### (4) Melting Point of the Oxide

The effect of the melting point of the oxide contained in the buffer layer on the coercive force Hc of the magnetic recording layer granular film was evaluated, and the melting point of the oxide contained in the sputtering target according to the present embodiment was determined. Specifically, evaluation was performed by measuring the coercive force Hc of the magnetic recording layer granular film formed on the buffer layer formed on the Ru underlayer. The composition of the buffer layer to be evaluated was Ru₅₀Co₂₅Cr₂₅-30 vol % oxide, and in regards to the composition of the sputtering target used for forming the buffer layer, the metal components were set to Ru₅₀Co₂₅Cr₂₅ and the volume fraction of oxide was set to 30 vol % relative to the entire sputtering target. In addition, the Hc in the case where a magnetic recording layer granular film was directly formed on the Ru underlayer without providing a buffer layer on the Ru underlayer was also evaluated. The thickness of the buffer layer was 2 nm, and the layer structure of the samples for measuring the coercive force Hc was, in order from the glass substrate side, Ta (5 nm, 0.6 Pa)/Ni₉₀W₁₀ (6 nm, 0.6 Pa)/Ru (10 nm, 0.6 Pa)/Ru (10 nm, 8 Pa)/buffer layer (2 nm, 0.6 Pa)/Co₈₀Pt₂₀-30 vol % B₂O₃ (16 nm, 4 Pa)/C (7 nm, 0.6 Pa) (hereinafter, this layer structure may be referred to as layer structure A). The numbers on the left side in parentheses indicate the film thickness, and the numbers on the right side indicate the pressure of an Ar atmosphere during sputtering. The magnetic recording layers granular film is Co₈₀Pt₂₀-30 vol % B₂O₃.

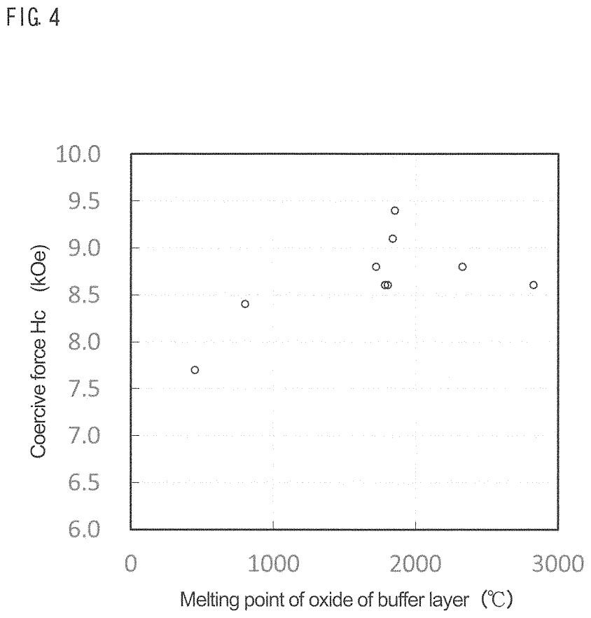

The measurement results of the coercive force Hc are shown in the following Table 1. FIG. 4 is a graph in which the horizontal axis shows the melting point of the oxide of the buffer layer and the vertical axis shows the coercive force Hc. Note that the data having no oxide in Table 1 is data obtained when a magnetic recording layer granular film is directly formed on the Ru underlayer without providing a buffer layer on the Ru underlayer.

TABLE 1

| | Melting point | Coercive force Hc |
|---|---|---|
| Oxide | (° C.) | (kOe) |
| None | — | 7.5 |
| B₂O₃ | 450 | 7.7 |
| MoO₃ | 802 | 8.4 |
| SiO₂ | 1723 | 8.8 |
| Ta₂O₅ | 1785 | 8.6 |
| CoO | 1805 | 8.6 |
| MnO | 1842 | 9.1 |
| TiO₂ | 1857 | 9.4 |
| Cr₂O₃ | 2330 | 8.8 |
| MgO | 2832 | 8.6 |

As can be seen from Table 1 and FIG. 4, up to about 1700° C., the coercive force Hc tends to increase as the melting point of the oxide contained in the buffer layer is higher, but when the melting point of the oxide contained in the buffer layer exceeds 1700° C., the coercive force Hc becomes almost constant even if the melting point of the oxide further rises.

Therefore, in the sputtering target according to the present embodiment, the melting point of the oxide to be contained is set at 1700° C. or more.

The coercive force Hc of each of the magnetic recording layer granular films formed on the buffer layers with different thicknesses was measured by a vibrating sample magnetometer (VSM), and the thickness of the buffer layer when the coercive force Hc of the magnetic recording layer granular film reaches its peak value was determined for each oxide to be contained. The results are shown in the following Table 2. FIG. 5 is a graph in which the horizontal axis shows the melting point of the oxide of the buffer layer and the vertical axis shows the thickness of the buffer layer when the coercive force Hc of the magnetic recording layer granular film reaches its peak value. The layer structure of the sample for measuring the coercive force Hc when the data in Table 2 and FIG. 5 are measured is the same as the “layer structure A” described above except for the thickness of the buffer layer.

TABLE 2

| | Melting point | Thickness of buffer layer when Hc |
|---|---|---|
| Oxide | (° C.) | reaches its peak value (nm) |
| B₂O₃ | 450 | 3.0 |
| SiO₂ | 1723 | 2.5 |
| TiO₂ | 1857 | 2.0 |
| Al₂O₃ | 2072 | 1.7 |
| Cr₂O₃ | 2330 | 1.4 |
| Y₂O₃ | 2410 | 1.0 |
| ZrO₂ | 2677 | 0.5 |

As can be seen from Table 2 and FIG. 5, the higher the melting point of the oxide contained in the buffer layer, the smaller the thickness of the buffer layer when the coercive force Hc reaches its peak value.

The smaller the thickness of the buffer layer when the coercive force Hc reaches its peak value, the shorter the magnetic path through which the magnetic flux from the write head is returned to the head again, and the stronger the write magnetic field can be. Therefore, the smaller the thickness of the buffer layer is, the better it is. When the melting point of the oxide to be contained in the buffer layer is 1860° C. or more, the thickness of the buffer layer when the coercive force Hc reaches its peak value is expected to be approximately below 2 nm, and therefore, the melting point of the oxide to be contained is preferably 1860° C. or more.

### (5) Content of the Oxide

From the viewpoint of increasing the coercive force Hc of the magnetic recording layer granular film formed on the buffer layer, the amount of oxide contained in the sputtering target according to the present embodiment is 20 vol % or more and 50 vol % or less relative to the entire sputtering target. From the viewpoint of more increasing the coercive force Hc of the magnetic recording layer granular film, it is more preferable that the amount of oxide contained in the sputtering target according to the present embodiment is 25 vol % or more and 40 vol % or less relative to the entire sputtering target. The above has been demonstrated in the examples described below.

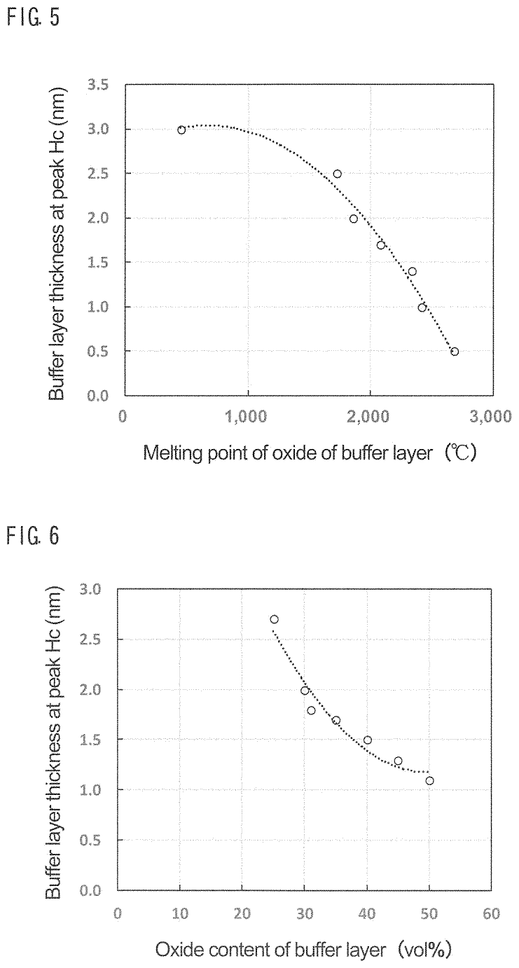

In addition, the composition of buffer layers was set to a Ru₅₀Co₂₅Cr₂₅-30 vol % TiO₂, and the buffer layers whose thickness were changed for each predetermined content (25 vol %, 30 vol %, 31 vol %, 35 vol %, 40 vol %, 45 vol %, 50 vol %) of the oxide (TiO₂) therein were prepared. The coercive force Hc of the magnetic recording layer granular film formed on each of the prepared buffer layers was measured by a vibrating sample magnetometer (VSM), and the thickness of the buffer layer when the coercive force Hc of the magnetic recording layer granular film reaches its peak value was determined for the each predetermined content of the oxide (TiO₂) of the buffer layers. The results are shown in the following Table 3. FIG. 6 is a graph in which the horizontal axis shows the oxide content of the buffer layer and the vertical axis shows the thickness of the buffer layer when the coercive force Hc of the magnetic recording layer granular film reaches its peak value. The layer structure of the samples for measuring the coercive force Hc is the same as the “layer structure A” described above in (4) except for the thickness of the buffer layer.

TABLE 3

| Content of TiO₂ | Thickness when Hc |
|---|---|
| (vol %) | reaches its peak value (nm) |
| 25 | 2.7 |
| 30 | 2.0 |
| 31 | 1.8 |
| 35 | 1.7 |
| 40 | 1.5 |
| 45 | 1.3 |
| 50 | 1.1 |

As can be seen from Table 3 and FIG. 6, the thickness of the buffer layer when the coercive force Hc reaches its peak value tends to decrease as the amount of the oxide (TiO₂) contained in the buffer layer increases.

The smaller the thickness of the buffer layer when the coercive force Hc of the magnetic recording layer granular film reaches its peak value, the shorter the magnetic path through which the magnetic flux from the write head is returned to the head again, and the stronger the write magnetic field can be. Therefore, the smaller the thickness of the buffer layer is, the better it is. When the amount of the oxide (TiO₂) to be contained in the buffer layer is 31 vol % or more, the thickness of the buffer layer when the coercive force Hc reaches its peak value is expected to be approximately below 2 nm, and therefore, the amount of the oxide to be contained is preferably 31 vol % or more and 50 vol % or less.

### (6) Specific Examples of the Oxides

The melting point of the oxide which can be contained for the sputtering target according to the present embodiment was explained in (4) and the content of the oxide was explained in (5). The oxides which can be contained for the sputtering target according to the present embodiment are specifically oxides of Si, Ta, Co, Mn, Ti, Cr, Mg, Al, Y, Zr, Hf, etc., and for example, SiO₂, Ta₂O₅, CoO, MnO, TiO₂, Cr₂O₃, MgO, Al₂O₃, Y₂O₃, ZrO₂, and HfO₂ can be cited.

The sputtering target according to the present embodiment can contain a plurality of kinds of oxides, and the melting point of oxide when the contained oxide is a plurality of kinds is calculated by a weighted average of the content ratio (volume ratio to the total of the contained oxides) of each of the oxides with respect to the melting point of each kind of the contained oxides.

### (7) Microstructure of the Sputtering Target

The microstructure of the sputtering target according to the present embodiment is not particularly limited, but it is preferable to form a microstructure in which a metal phase and an oxide phase are finely dispersed and mutually dispersed. By forming such a microstructure, defects such as nodules and particles are less likely to occur when sputtering is performed.

### (8) Hardness of the Sputtering Target

From the viewpoint of suppressing the occurrence of cracks at the interface between the metal phase and the oxide phase and reducing the occurrence of cracks of the sputtering target and defects such as nodules and particles, the hardness of the sputtering target according to the present embodiment is preferably hard. Specifically, it is preferable that the hardness is 920 or more by Vickers hardness HV10.

Vickers hardness HV10 refers to Vickers hardness obtained by measuring at a test force of 10 kg.

### (9) Process for Production of the Sputtering Target

A sputtering target having a composition of Ru₅₀Co₂₅Cr₂₅-30 vol % TiO₂ included in the range of sputtering targets according to the present embodiment will be taken as a specific example, and an example of a process for production will be described below. However, the process for production of the sputtering target according to the present embodiment is not limited to the following specific examples.

(9-1) Preparation of Ru₅₀Co₂₅Cr₂₅ Alloy-Atomized Powder

The metallic Ru, the metallic Co, and the metallic Cr are weighed so that the atomic ratio of the metallic Ru is 50 at %, the atomic ratio of the metallic Co is 25 at %, and the atomic ratio of the metal Cr is 25 at % relative to the total amount of the metallic Ru, the metallic Co, and the metallic Cr, and a molten RuCoCr is prepared. Then, gas atomization is performed to prepare RuCoCr alloy-atomized powder. The prepared RuCoCr alloy-atomized powder is classified so that the particle diameter becomes not larger than a predetermined particle diameter (for example, 106 μm or smaller).

### (9-2) Preparation of Powder Mixture for Pressure Sintering

TiO₂ powder is added to the RuCoCr alloy-atomized powder prepared in (9-1) so as to be 30 vol %, and mixed and dispersed with a ball mill to prepare a powder mixture for pressure sintering.

By mixing and dispersing the RuCoCr alloy-atomized powder and the TiO₂ powder with a ball mill, a powder mixture for pressure sintering in which the RuCoCr alloy-atomized powder and the TiO₂ powder are finely dispersed can be prepared.

From the viewpoint of increasing the coercive force Hc of the magnetic recording layer granular film formed on the buffer layer formed by using the obtained sputtering target, the volume fraction of the TiO₂ powder relative to the whole of the powder mixture for pressure sintering is preferably 20 vol % or more and 50 vol % or less, and more preferably 25 vol % or more and 40 vol % or less.

In addition, from the viewpoint of reducing the thickness of the buffer layer when the coercive force Hc of the magnetic recording layer granular film reaches its peak value, the volume fraction of the TiO₂ powder relative to the whole of the powder mixture for pressure sintering is preferably 31 vol % or more and 50 vol % or less.

### (9-3) Molding

The powder mixture for pressure sintering prepared in (9-2) is pressure-sintered and molded using, for example, a vacuum hot press method to produce a sputtering target. Since the powder mixture for pressure sintering prepared in (9-2) is mixed and dispersed with a ball mill, and the RuCoCr alloy-atomized powder and the TiO₂ powder are finely dispersed, defects such as generation of nodules and particles are unlikely to occur during sputtering by using the sputtering targets obtained by this production process.

The method for pressure sintering the powder mixture for pressure sintering is not particularly limited. The method may be a method other than the vacuum hot press method, and may be, for example, the HIP method or the like.

In the examples of the production process described above, the RuCoCr alloy-atomized powder is prepared using the atomization method, and a TiO₂ powder is added to the prepared RuCoCr alloy-atomized powder and mixed and dispersed with the ball mill to prepare the powder mixture for pressure sintering. Instead of using the RuCoCr alloy-atomized powder, a Ru single powder, a Co single powder, and a Cr single powder may be used. In this case, a Ru single powder, a Co single powder, a Cr single powder, and a TiO₂ powder are mixed and dispersed with a ball mill to prepare a powder mixture for pressure sintering.

### (10) Preferred Particle Diameter of the Raw Material Powder

At the time of sputtering, a surface of the sputtering target opposite to the sputtering surface is cooled (hereinafter, the sputtering surface referred to as a front surface, and a surface of the sputtering target opposite to the sputtering surface referred to as a back surface). For this reason, a temperature difference occurs between the front surface and the back surface of the sputtering target, and the sputtering target is warped so that the front surface becomes a convex surface. Due to this phenomenon, a stress load is applied to the sputtering target, which may lead to breakage, which is a problem.

The sputtering target according to the present invention is a sputtering target containing a metal and an oxide, and cracks that cause fracture occur at the interface between the metal phase and the oxide phase.

In order to prevent the occurrence and development of cracks, it is desirable to disperse the metal powder and the oxide powder, which are the raw material powders, as evenly and finely as possible. Therefore, the smaller the average particle diameter of the raw material powder (the metal powder and the oxide powder) used for producing the sputtering target according to the present invention is, the more preferable it is.

When a metal having a high malleability (for example, Ru powder, Co powder, or Pt powder) is used as the raw material powder, the average particle diameter is preferably less than 5 μm, and more preferably less than 3 μm because it is difficult to make the metal fine by mixing. From the viewpoint of making the particles disperse as evenly and finely as possible, it is preferable that the average particle diameter is small, and the lower limit of the average particle diameter is not particularly limited. However, a lower limit may be set in consideration of ease of handling, cost, and the like, and when a metal having a high malleability (for example, Ru powder, Co powder, or Pt powder) is used as the raw material powder, for example, the lower limit of the average particle diameter may be set to 0.5 μm.

When a metal having low malleability (for example, Cr powder) is used as a raw material powder, it can be used as a raw material powder even if the average particle diameter is not so small because refinement by mixing can be expected to some extent. However, even when a metal having low malleability (for example, Cr powder) is used as a raw material powder, it is desirable to have a smaller average particle diameter, and therefore, when a metal having a low malleability (for example, Cr powder) is used as the raw material powder, the average particle diameter is preferably less than 50 μm, and more preferably less than 30 μm. From the viewpoint of making the particles disperse as evenly and finely as possible, it is preferable that the average particle diameter is small, and the lower limit of the average particle diameter is not particularly limited. However, a lower limit may be set in consideration of ease of handling, cost, and the like, and when a metal having a low malleability (for example, Cr powder) is used as the raw material powder, for example, the lower limit of the average particle diameter may be set to 0.5 μm.

The oxide powder is difficult to refine by mixing because of the hardness of the oxide itself. For this reason, it is preferable that the average particle diameter of the oxide powder used as the raw powder is less than 1 μm, and less than 0.5 μm is more preferable. From the viewpoint of making the particles disperse as evenly and finely as possible, it is preferable that the average particle diameter is small, and the lower limit of the average particle diameter is not particularly limited. However, a lower limit may be set in consideration of ease of handling, cost, and the like, and the lower limit of the average particle diameter of the oxide powder used as the raw powder may be, for example, 0.05 μm.

The average particle diameter of the raw powder described above may be determined by image analysis using a scanning electron microscope (SEM) (for example, X Vision 200 DB by Hitachi High-Tech Corporation) or by measuring the particle size distribution using a particle size distribution measurement device (for example, Microtrac MT3000II by Microtrac Bell Corporation).

### (11) Applicable Magnetic Recording Layer Granular Films

The composition of the magnetic recording layer granular film to be formed on the buffer layer provided on the Ru underlayer by using the sputtering target according to the present embodiment is not particularly limited. A buffer layer was prepared on the Ru underlayer by using the sputtering target according to the present embodiment, and a magnetic recording layer granular film was laminated on the buffer layer, and a sample for magnetic property measurement was prepared, and the coercive force Hc was measured, and as a result, it was confirmed that the coercive force Hc of the magnetic recording layer granular films improved. The specific examples of the magnetic recording layer granular films whose coercive force Hc was confirmed to be improved are as follows.

### (Co-20Pt)-30 vol % WO₃

### (Co-5Cr-20Pt)-30 vol % WO₃

### (Co-20Pt)-30 vol % SiO₂

### (Co-5Cr-20Pt)-30 vol % SiO₂

### (Co-20Pt)-30 vol % TiO₂

### (Co-5Cr-20Pt)-30 vol % TiO₂

(Co-20Pt)-30 vol % Cr₂O₃
(Co-5Cr-20Pt)-30 vol % Cr₂O₃

### (Co-20Pt)-30 vol % MnO₃

### (Co-5Cr-20Pt)-30 vol % MnO₃

### (Co-20Pt)-30 vol % WO₂

### (Co-20Pt)-30 vol % MnO

### (Co-20Pt)-30 vol % MnO₂

(Co-20Pt)-40 vol % B₂O₃
(Co-20Pt)-35 vol % B₂O₃
(Co-20Pt)-30 vol % B₂O₃
(Co-20Pt)-25 vol % B₂O₃
(Co-20Pt)-20 vol % B₂O₃
(Co-20Pt)-10 vol % B₂O₃
(Co-20Pt)-30 vol % Y₂O₃
(Co-20Pt)-30 vol % Mn₃O₄
(Co-20Pt)-30 vol % Nb₂O₅

### (Co-20Pt)-30 vol % ZrO₂

(Co-20Pt)-30 vol % Ta₂O₅
(Co-20Pt)-30 vol % Al₂O₃
(Co-20Pt)-10 vol % SiO₂-10 vol % TiO₂-10 vol % Cr₂O₃
(Co-20Pt)-10 vol % SiO₂-10 vol % Cr₂O₃-10 vol % B₂O₃
(Co-20Pt)-10 vol % SiO₂-10 vol % TiO₂-10 vol % CoO
(Co-5Cr-20Pt)-15 vol % SiO₂-15 vol % Co₃O₄

### (Co-5Cr-20Pt)-15 vol % SiO₂-15 vol % CoO

(Co-20Pt)-15 vol % SiO₂-15 vol % Co₃O₄

### (Co-20Pt)-15 vol % SiO₂-15 vol % CoO

(Co-5Cr-20Pt)-30 vol % Co₃O₄

### (Co-5Cr-20Pt)-30 vol % CoO

(Co-20Pt)-30 vol % Co₃O₄

### (Co-20Pt)-30 vol % CoO

(Co-20Pt)-15 vol % B₂O₃-15 vol % SiO₂
(Co-20Pt)-15 vol % B₂O₃-15 vol % TiO₂
(Co-20Pt)-15 vol % B₂O₃-15 vol % CoO
(Co-20Pt)-15 vol % B₂O₃-15 vol % Cr₂O₃
(Co-20Pt)-15 vol % B₂O₃-15 vol % Co₃O₄
(Co-5B-20Pt)-30 vol % Cr₂O₃

### (Co-5B-20Pt)-30 vol % TiO₂

(Co-20Pt)-15 vol % Cr₂O₃-15 vol % WO₃

### (Co-5Ru-20Pt)-30 vol % TiO₂

### (Co-5Ru-20Pt)-30 vol % SiO₂

### (Co-5B-20Pt)-30 vol % SiO₂

(Co-5Ru-20Pt)-30 vol % Cr₂O₃
(Co-5Ru-20Pt)-15 vol % TiO₂-15 vol % Cr₂O₃
(Co-5Ru-20Pt)-10 vol % SiO₂-10 vol % TiO₂-10 vol % Cr₂O₃

### (Co-5B-20Pt)-30 vol % WO₃

(Co-20Pt)-15 vol % SiO₂-15 vol % TiO₂
(Co-20Pt)-15 vol % TiO₂-15 vol % Cr₂O₃

### (Co-20Pt)-15 vol % TiO₂-15 vol % CoO

(Co-20Pt)-25 vol % B₂O₃-5 vol % Cr₂O₃
(Co-20Pt)-25 vol % B₂O₃-5 vol % Al₂O₃
(Co-20Pt)-25 vol % B₂O₃-5 vol % ZrO₂
(Co-20Pt)-15 vol % B₂O₃-15 vol % Nb₂O₅

### (Co-20Pt)-30 vol % MgO

(Co-20Pt)-30 vol % Fe₂O₃
(Co-20Pt)-25 vol % B₂O₃-5 vol % MgO
(Co-20Pt)-15 vol % B₂O₃-15 vol % Ta₂O₅
(Co-20Pt)-15 vol % B₂O₃-15 vol % MoO₃
(Co-20Pt)-15 vol % B₂O₃-15 vol % WO₃
(Co-20Pt)-20 vol % SiO₂-5 vol % TiO₂-5 vol % CoO
(Co-20Pt)-20 vol % SiO₂-5 vol % TiO₂-5 vol % Cr₂O₃
(Co-20Pt)-5 vol % SiO₂-20 vol % Cr₂O₃-5 vol % B₂O₃
(Co-20Pt)-5 vol % SiO₂-20 vol % TiO₂-5 vol % Cr₂O₃
(Co-20Pt)-5 vol % SiO₂-5 vol % Cr₂O₃-20 vol % B₂O₃
(Co-20Pt)-5 vol % SiO₂-5 vol % TiO₂-20 vol % Cr₂O₃
(Co-20Pt)-20 vol % SiO₂-5 vol % Cr₂O₃-5 vol % B₂O₃
(Co-20Pt)-5 vol % SiO₂-20 vol % TiO₂-5 vol % CoO
(Co-20Pt)-5 vol % SiO₂-5 vol % TiO₂-20 vol % CoO
(Co-20Pt)-10 vol % SiO₂-10 vol % CoO-10 vol % B₂O₃
(Co-20Pt)-10 vol % TiO₂-10 vol % Co₃O₄-10 vol % B₂O₃
(Co-20Pt)-15 vol % TiO₂-15 vol % Co₃O₄
(Co-20Pt)-10 vol % TiO₂-10 vol % CoO-10 vol % B₂O₃
(Co-20Pt)-10 vol % SiO₂-10 vol % Co₃O₄-10 vol % B₂O₃
(Co-20Pt)-10 vol % TiO₂-10 vol % Cr₂O₃-10 vol % B₂O₃
(Co-20Pt)-10 vol % SiO₂-10 vol % TiO₂-10 vol % B₂O₃
(Co-20Pt)-5 vol % SiO₂-5 vol % CoO-20 vol % B₂O₃
(Co-20Pt)-5 vol % SiO₂-5 vol % Co₃O₄-20 vol % B₂O₃
(Co-20Pt)-10 vol % TiO₂-20 vol % B₂O₃
(Co-20Pt)-15 vol % B₂O₃-15 vol % ZrO₂
(Co-20Pt)-5 vol % SiO₂-5 vol % TiO₂-20 vol % B₂O₃
(Co-20Pt)-5 vol % TiO₂-5 vol % Cr₂O₃-20 vol % B₂O₃
(Co-20Pt)-25 vol % B₂O₃-5 vol % SiO₂
(Co-20Pt)-25 vol % B₂O₃-5 vol % TiO₂
(Co-20Pt)-20 vol % B₂O₃-10 vol % SiO₂
(Co-20Pt)-20 vol % B₂O₃-10 vol % Cr₂O₃
(Co-20Pt)-15 vol % B₂O₃-15 vol % Y₂O₃
(Co-5Cr-20Pt)-30 vol % B₂O₃
(Co-20Pt-5Ru)-30 vol % B₂O₃
(Co-20Pt-5B)-30 vol % B₂O₃

### EXAMPLES

Examples and comparative examples are described below.

### Example 1

The entire composition of the target prepared as Example 1 is Ru₅₀Co₂₅Cr₂₅-30 vol % TiO₂.

Ru powder (average particle diameter of greater than 5 μm and less than 50 μm), Co powder (average particle diameter of greater than 5 μm and less than 50 μm), and Cr powder (average particle diameter of greater than 50 μm and less than 100 μm) weighed so that the composition is Ru:50 at %, Co:25 at %, and Cr:25 at %, and TiO₂ powder (average particle diameter of less than 100 μm) weighed so that the volume fraction is 30 vol %, were mixed and crushed in a planetary ball mill to obtain a powder mixture for pressure sintering.

The obtained powder mixture for pressure sintering was subjected to hot pressing under the condition of sintering temperature: 920° C., pressure: 24.5 MPa, time: 30 min, and atmosphere: 5×10⁻² Pa or lower to prepare a sintered test piece (φ30 ram). The relative density of the prepared sintered test piece was 98.5%. The calculated density is 8.51 g/cm³. The cross section in the thickness direction of the obtained sintered test piece was observed with a metallurgical microscope, and it was found that the metal phase (Ru₅₀Co₂₅Cr₂₅ alloy phase) and the oxide phase (TiO₂ phase) were finely dispersed.

Next, the prepared powder mixture for pressure sintering was subjected to hot pressing under the conditions of sintering temperature: 920° C., pressure:24.5 MPa, time: 60 min, and atmosphere: 5×10⁻² Pa or lower to prepare a target with φ153.0×1.0 mm+φ161.0×4.0 mm. The relative density of the prepared target was 98.8%.

A buffer layer made of Ru₅₀Co₂₅Cr₂₅-30 vol % TiO₂ was formed on a Ru underlayer by sputtering with DC sputtering device by using the prepared target to produce a sample for determining magnetic properties and a sample for observing texture. The layer structure of these samples is, in order from the glass substrate side, Ta (5 nm, 0.6 Pa)/Ni₉₀W₁₀ (6 nm, 0.6 Pa)/Ru (10 nm, 0.6 Pa)/Ru (10 nm, 8 Pa)/buffer layer (2 nm, 0.6 Pa)/magnetic recording layer granular film (16 nm, 4 Pa)/C (7 nm, 0.6 Pa). The number on the left side in parenthesis indicates the film thickness, and the number on the right side indicates the pressure of an Ar atmosphere during sputtering. The buffer layer formed by using the prepared target in Example 1 was Ru₅₀Co₂₅Cr₂₅-30 vol % TiO₂ having a thickness of 2 nm, and the magnetic recording layer granular film formed on the buffer layer was Co₈₀Pt₂₀-30 vol % B₂O₃ having a thickness of 16 nm. The magnetic recording layer granular film was deposited at room temperature without heating the substrate during film deposition.

A vibrating sample magnetometer (VSM) was used to measure the coercive force Hc of a sample for determining magnetic properties. The measurement results of the coercive force Hc are shown in Table 4 together with the results of other examples and comparative examples. The coercive force Hc of Example 1 was 9.4 kOe, and a good coercive force Hc was obtained in Example 1.

For measuring the lattice constant “a”, an X-ray diffraction apparatus (X-ray diffraction apparatus ATX-G/TS for evaluating thin film structures manufactured by Rigaku Corporation) was used with CuKα rays (wavelengths of 0.154 nm). And the lattice constant “a” was calculated from the angle of the diffraction line peak.

Further, it was confirmed from the results of X-ray diffraction measurements in the in-plane direction of the samples for magnetic property measurements that the CoPt alloys grains in the magnetic recording layer granular film were oriented in the C-plane.

Transmission electron microscopy (TEM) and scanning transmission electron microscopy (STEM) were used to evaluate the structures of the sample for observing texture.

FIGS. 1(A) to (C) are results measured by scanning transmission electron microscope (STEM) for the magnetic recording medium 10 of Example 1. FIG. 1(A) is a STEM (scanning transmission electron microscope) photograph of a perpendicular cross section of the magnetic recording medium 10 of Example 1. FIGS. 1(B) and (C) show the results of energy dispersive X-ray analysis by STEM (scanning transmission electron microscope); FIG. 1(B) is an analysis result of Cr, and FIG. 1(C) is an analysis result of Ru.

The buffer layer 14 of this example 1 is first formed on the Ru underlayer 12, and then the magnetic recording layer granular film 16 is formed on the buffer layer 14. As shown in FIG. 1(A), the magnetic crystal grains (Co₈₀Pt₂₀ alloy grains) 16A of the magnetic recording layer granular film 16 are well separated each other by the oxide (B₂O₃) phase 16B. This is considered to be because the magnetic grains (Co₈₀Pt₂₀ alloy grains) 16A of the magnetic recording layer granular film 16 grow on the alloy (Ru₅₀Co₂₅Cr₂₅) phase 14A which is a metal component of the buffer layer 14, and the oxide (B₂O₃) phase 16B of the magnetic recording layer granular film 16 deposits on the oxide (TiO₂) phase 14B which is an oxide component of the buffer layer 14.

Further, the magnetic recording layer granular film of the samples for observing texture was observed by transmission electron microscope (TEM) in a horizontal cross section (a horizontal cross section at a height position 40 Å above the upper surface of the Ru underlayer), which is substantially perpendicular to the height directions of the columnar CoPt alloy crystal grains. The plane TEM photograph of the observation result is shown in FIG. 2 together with the plane TEM photograph of Comparative Example 1, in which the observation position is the same observation position as the plane TEM photograph of Example 1. FIG. 2(A) is a plane TEM photograph of Example 1, and FIG. 2(B) is a plane TEM photograph of Comparative Example 1.

As shown in FIGS. 1(A) and 2(A), in the present example 1, the magnetic crystal grains (Co₈₀Pt₂₀ alloy grains) 16A of the magnetic recording layer granular film 16 formed on the buffer layer 14 are neatly separated by the oxide (B₂O₃) phase 16B. As a result, the magnetic interaction between the magnetic crystal grains (Co₈₀Pt₂₀ alloy grains) 16A is reduced, and it is considered that a satisfactory value for the coercive force Hc of the magnetic recording layer granular film 16 is obtained in the present example 1.

### Examples 2-51, Comparative Examples 1-9

Samples for determining magnetic properties and samples for observing texture were prepared in the same manner as in Example 1, except that the composition of the target was changed from Example 1, and the same evaluations were performed as in Example 1 for Examples 2-51 and Comparative Examples 1-9.

The measurement results of the coercive force Hc of Examples 1 to 51 and Comparative Examples 1 to 9 are shown in Table 4 together with the composition of the target.

TABLE 4

| | | lattice constant | | | Thickness | |
|---|---|---|---|---|---|---|
| | | “a” of the | Thickness | | of magnetic | |
| | | hep structure | of BL | Composition of | layer | Hc |
| | Composition of buffer layer | (Å) | (nm) | magnetic layer | (nm) | (kOe) |
| Comparative | None | — | — | Co80Pt20-30vol % B₂O₃ | 16 | 7.5 |
| Example 1 | | | | | | |
| Comparative | Ru45Cr55-30vol % TiO₂ | 2.66 | 2 | Co80Pt20-30vol % B₂O₃ | 16 | 7.6 |
| Example 2 | | | | | | |
| Comparative | Ru45Co55-30vol % TiO₂ | 2.60 | 2 | Co80Pt20-30vol % B₂O₃ | 16 | 7.7 |
| Example 3 | | | | | | |
| Comparative | Ru50Co25Cr25-30vol % B₂O₃ | 2.63 | 2 | Co80Pt20-30vol % B₂O₃ | 16 | 8.1 |
| Example 4 | | | | | | |
| Comparative | Ru50Co25Cr25-30vol % MoO₃ | 2.63 | 2 | Co80Pt20-30vol % B₂O₃ | 16 | 8.4 |
| Example 5 | | | | | | |
| Comparative | Ru50Co25Cr25-19vol % TiO₂ | 2.63 | 2 | Co80Pt20-30vol % B₂O₃ | 16 | 8.4 |
| Example 6 | | | | | | |
| Comparative | Ru50Co25Cr25-51vol % TiO₂ | 2.63 | 2 | Co80Pt20-30vol % B₂O₃ | 16 | 8.3 |
| Example 7 | | | | | | |
| Comparative | Ru84Pt16-30vol % TiO₂ | 2.73 | 2 | Co80Pt20-30vol % B₂O₃ | 16 | 7.8 |
| Example 8 | | | | | | |
| Comparative | Co50Cr50-30vol % TiO₂ | 2.55 | 2 | Co80Pt20-30vol % B₂O₃ | 16 | 8.1 |
| Example 9 | | | | | | |
| Example 1 | Ru50Co25Cr25-30vol % TiO₂ | 2.63 | 2 | Co80Pt20-30vol % B₂O₃ | 16 | 9.4 |
| Example 2 | Ru46Cr54-30vol % TiO₂ | 2.66 | 2 | Co80Pt20-30vol % B₂O₃ | 16 | 8.6 |
| Example 3 | Ru60Cr40-30vol % TiO₂ | 2.68 | 2 | Co80Pt20-30vol % B₂O₃ | 16 | 8.7 |
| Example 4 | Ru80Cr20-30vol % TiO₂ | 2.70 | 2 | Co80Pt20-30vol % B₂O₃ | 16 | 9.2 |
| Example 5 | Ru-30vol % TiO₂ | 2.71 | 2 | Co80Pt20-30vol % B₂O₃ | 16 | 9.1 |
| Example 6 | Ru80Co20-30vol % TiO₂ | 2.68 | 2 | Co80Pt20-30vol % B₂O₃ | 16 | 9.3 |
| Example 7 | Ru60Co40-30vol % TiO₂ | 2.64 | 2 | Co80Pt20-30vol % B₂O₃ | 16 | 8.9 |
| Example 8 | Ru46Co54-30vol % TiO₂ | 2.60 | 2 | Co80Pt20-30vol % B₂O₃ | 16 | 8.6 |
| Example 9 | Ru90Pt10-30vol % TiO₂ | 2.72 | 2 | Co80Pt20-30vol % B₂O₃ | 16 | 9.3 |
| Example 10 | Ru85Pt15-30vol % TiO₂ | 2.72 | 2 | Co80Pt20-30vol % B₂O₃ | 16 | 9.5 |
| Example 11 | Ru60Co25Cr15-30vol % TiO₂ | 2.65 | 2 | Co80Pt20-30vol % B₂O₃ | 16 | 9.5 |
| Example 12 | Ru70Co25Cr5-30vol % TiO₂ | 2.65 | 2 | Co80Pt20-30vol % B₂O₃ | 16 | 9.3 |
| Example 13 | Ru60Co15Cr25-30vol % TiO₂ | 2.66 | 2 | Co80Pt20-30vol % B₂O₃ | 16 | 9.4 |
| Example 14 | Ru70Co5Cr25-30vol % TiO₂ | 2.68 | 2 | Co80Pt20-30vol % B₂O₃ | 16 | 9.5 |
| Example 15 | Ru80Co10Cr10-30vol % TiO₂ | 2.69 | 2 | Co80Pt20-30vol % B₂O₃ | 16 | 9.2 |
| Example 16 | Ru40Co30Cr30-30vol % TiO₂ | 2.62 | 2 | Co80Pt20-30vol % B₂O₃ | 16 | 9.5 |
| Example 17 | Ru20Co40Cr40-30vol % TiO₂ | 2.59 | 2 | Co80Pt20-30vol % B₂O₃ | 16 | 9.5 |
| Example 18 | Ru50Co25Pt25-30vol % TiO₂ | 2.70 | 2 | Co80Pt20-30vol % B₂O₃ | 16 | 9.2 |
| Example 19 | Ru60Co25Pt15-30vol % TiO₂ | 2.69 | 2 | Co80Pt20-30vol % B₂O₃ | 16 | 9.3 |
| Example 20 | Ru70Co25Pt5-30vol % TiO₂ | 2.68 | 2 | Co80Pt20-30vol % B₂O₃ | 16 | 9.5 |
| Example 21 | Ru60Co15Pt25-30vol % TiO₂ | 2.71 | 2 | Co80Pt20-30vol % B₂O₃ | 16 | 8.8 |
| Example 22 | Ru70Co5Pt25-30vol % TiO₂ | 2.72 | 2 | Co80Pt20-30vol % B₂O₃ | 16 | 9.1 |
| Example 23 | Ru80Co10Pt10-30vol % TiO₂ | 2.69 | 2 | Co80Pt20-30vol % B₂O₃ | 16 | 8.7 |
| Example 24 | Ru40Co30Pt30-30vol % TiO₂ | 2.68 | 2 | Co80Pt20-30vol % B₂O₃ | 16 | 8.9 |
| Example 25 | Ru20Co50Pt30-30vol % TiO₂ | 2.64 | 2 | Co80Pt20-30vol % B₂O₃ | 16 | 9.1 |
| Example 26 | Ru40Co15Cr25Pt20-30vol % TiO₂ | 2.69 | 2 | Co80Pt20-30vol % B₂O₃ | 16 | 9.7 |
| Example 27 | Ru40Co25Cr15Pt20-30vol % TiO₂ | 2.69 | 2 | Co80Pt20-30vol % B₂O₃ | 16 | 10.1 |
| Example 28 | Ru45Co25Cr25Pt5-30vol % TiO₂ | 2.64 | 2 | Co80Pt20-30vol % B₂O₃ | 16 | 9.7 |
| Example 29 | Ru40Co25Cr25Pt10-30vol % TiO₂ | 2.66 | 2 | Co80Pt20-30vol % B₂O₃ | 16 | 9.9 |
| Example 30 | Ru35Co25Cr25Pt15-30vol % TiO₂ | 2.68 | 2 | Co80Pt20-30vol % B₂O₃ | 16 | 10.2 |
| Example 31 | Ru30Co25Cr25Pt20-30vol % TiO₂ | 2.69 | 2 | Co80Pt20-30vol % B₂O₃ | 16 | 10.5 |
| Example 32 | Ru25Co25Cr25Pt25-30vol % TiO₂ | 2.72 | 2 | Co80Pt20-30vol % B₂O₃ | 16 | 9.8 |
| Example 33 | Ru85Co5Cr5Pt5-30vol % TiO₂ | 2.70 | 2 | Co80Pt20-30vol % B₂O₃ | 16 | 8.7 |
| Example 34 | Ru70Co10Cr10Pt10-30vol % TiO₂ | 2.68 | 2 | Co80Pt20-30vol % B₂O₃ | 16 | 8.9 |
| Example 35 | Ru55Co15Cr15Pt15-30vol % TiO₂ | 2.66 | 2 | Co80Pt20-30vol % B₂O₃ | 16 | 9.1 |
| Example 36 | Ru50Co25Cr25-30vol % SiO₂ | 2.63 | 2 | Co80Pt20-30vol % B₂O₃ | 16 | 8.8 |
| Example 37 | Ru50Co25Cr25-30vol % Ta₂O₅ | 2.63 | 2 | Co80Pt20-30vol % B₂O₃ | 16 | 8.6 |
| Example 38 | Ru50Co25Cr25-30vol % CoO | 2.63 | 2 | Co80Pt20-30vol % B₂O₃ | 16 | 8.6 |
| Example 39 | Ru50Co25Cr25-30vol % MnO | 2.63 | 2 | Co80Pt20-30vol % B₂O₃ | 16 | 9.1 |
| Example 40 | Ru50Co25Cr25-30vol % Cr₂O₃ | 2.63 | 2 | Co80Pt20-30vol % B₂O₃ | 16 | 8.8 |
| Example 41 | Ru50Co25Cr25-30vol % MgO | 2.63 | 2 | Co80Pt20-30vol % B₂O₃ | 16 | 8.6 |
| Example 42 | Ru50Co25Cr25-30vol % Al₂O₃ | 2.63 | 2 | Co80Pt20-30vol % B₂O₃ | 16 | 8.8 |
| Example 43 | Ru50Co25Cr25-30vol % Y₂O₃ | 2.63 | 2 | Co80Pt20-30vol % B₂O₃ | 16 | 8.9 |
| Example 44 | Ru50Co25Cr25-30vol % ZrO₂ | 2.63 | 2 | Co80Pt20-30vol % B₂O₃ | 16 | 9.0 |
| Example 45 | Ru50Co25Cr25-30vol % HfO₂ | 2.63 | 2 | Co80Pt20-30vol % B₂O₃ | 16 | 9.1 |
| Example 46 | Ru50Co25Cr25-20vol % TiO₂ | 2.63 | 2 | Co80Pt20-30vol % B₂O₃ | 16 | 9.0 |
| Example 47 | Ru50Co25Cr25-25vol % TiO₂ | 2.63 | 2 | Co80Pt20-30vol % B₂O₃ | 16 | 9.2 |
| Example 48 | Ru50Co25Cr25-35vol % TiO₂ | 2.63 | 2 | Co80Pt20-30vol % B₂O₃ | 16 | 9.4 |
| Example 49 | Ru50Co25Cr25-40vol % TiO₂ | 2.63 | 2 | Co80Pt20-30vol % B₂O₃ | 16 | 9.2 |
| Example 50 | Ru50Co25Cr25-45vol % TiO₂ | 2.63 | 2 | Co80Pt20-30vol % B₂O₃ | 16 | 9.0 |
| Example 51 | Ru50Co25Cr25-50vol % TiO₂ | 2.63 | 2 | Co80Pt20-30vol % B₂O₃ | 16 | 8.8 |

As a result of observing Examples 2 to 51 by a transmission electron microscope (TEM), it was confirmed that a magnetic recording layer granular film having a structure in which magnetic crystal grains were separated by an oxide phase in the same manner as Example 1 was obtained.

In contrast, in the magnetic recording layer granular film Co₈₀Pt₂₀-30 vol % B₂O₃ of the magnetic recording medium of Comparative Example 1 in which the magnetic recording layer granular film Co₈₀Pt₂₀-30 vol % B₂O₃ was directly provided on a Ru underlayer without providing a buffer layer between the Ru underlayer and the magnetic recording layer granular film, as shown in the plane TEM photograph of FIG. 2(B) (horizontal cross-section at a height of 40 Å above the upper surface of the Ru underlayer), it was confirmed that the boundaries between the magnetic crystal grains (Co₈₀Pt₂₀ alloy grains) 56A of the magnetic recording layer granular film 56 became unclear and the isolation by the oxide (B₂O₃) phase 56B became inadequate. In addition, as a result of observing Comparative Examples 2, 4 to 6, and 9 which are not included in the scope of the present invention by a transmission electron microscope (TEM), it was confirmed that the separation of the magnetic crystal grains by the oxide phase was insufficient in the same manner as in Comparative Example 1.

### (Discussion)

As shown in Table 4, in the samples for determining magnetic properties of Examples 1 to 51 included in the scope of the present invention, the coercive force Hc was as large as 8.6 kOe to 10.5 kOe, and a satisfactory coercive force Hc was obtained.

In contrast, as shown in Table 4, in the samples for determining magnetic properties of Comparative Examples 1 to 9 which are not included in the range of the present invention, the coercive force Hc is as small as 7.5 kOe to 8.4 kOe.

The reason why the satisfactory coercive force Hc was obtained in the samples for determining magnetic properties of Examples 1 to 51 included in the scope of the present invention is considered to be that, as shown in, for example, FIGS. 1(A) and 2(A) for Example 1, the magnetic crystal grains of the magnetic recording layer granular film formed on the buffer layer are in a state of being neatly separated by the oxide phase, and the magnetic coupling between the magnetic crystal grains is reduced.

Therefore, it is considered that the buffer layer formed on the Ru underlayer by using the sputtering target of Examples 1 to 51 serves to satisfactorily separate the magnetic crystal grains of the magnetic recording layer granular film formed thereon, and reduce the magnetic interaction between the magnetic crystal grains, and consequently increase the coercive force Hc of the magnetic recording layer granular film.

In contrast, the reason why the coercive force Hc of the samples for determining magnetic properties of comparative examples 1, 2, 4 to 6, and 9 are smaller as compared with Examples 1 to 51 is considered to be that, as shown, for example, in FIG. 2(B) for comparative example 1, the boundary between magnetic crystal grains of the magnetic recording layer granular film is obscured, and the separation by the oxide phase is inadequate, and consequently the magnetic coupling between the magnetic crystal grains is larger.

In Comparative Example 3, it is considered that the coercive force Hc is reduced because the Ru₄₅Co₅₅ alloy, which is the metal component of the buffer layer, has magnetism.

In Comparative Example 7, the reason why the coercive force Hc is reduced is considered to be that the oxide content of the buffer layer is large, so the crystal orientation of the metal component of the buffer layer is deteriorated, and consequently the crystal orientation of the magnetic recording layer granular film stacked on the buffer layer is deteriorated.

In Comparative Example 8, the reason why the coercive force Hc is reduced is considered to be that the lattice constant “a” of the hcp structure of the buffer layer is larger than the lattice constant “a” of the hcp structure of Ru (2.72 Å), so the crystal orientation is deteriorated.

In Examples 1 and 46 to 51, the composition of sputtering targets is Ru₅₀Co₂₅Cr₂₅—TiO₂, and the content of the oxide (TiO₂) is varied from 20 Vol % to 50 Vol %. In Examples 1 and 47 to 49, where the content of the oxide (TiO₂) is within the range of 25 vol % or more 40 vol % or less, the coercive force Hc is larger than 9.0, and particularly satisfactory results are obtained. Therefore, the range of the oxide content of the sputtering target according to the present invention is preferably 25 vol % or more and 40 vol % or less.

### (Reference Data (the Hardness of the Sputtering Target))

The particle diameters of Ru powder, Co powder, Cr powder, and TiO₂ powder used in the preparation of the sputtering target (Ru₅₀Co₂₅Cr₂₅-30 vol % TiO₂) of Example 1 described above are as follows.

Ru powder: Average particle diameter of less than 5 μm

Co powder: Average particle diameter of less than 5 μm

Cr powder: Average particle diameter of less than 50 μm

TiO₂ powder: Average particle diameter of less than 5 μm

And the hardness of the obtained sputtering target was 964 by Vickers hardness HV10.

In contrast, the particle diameters of Ru powder, Co powder, Cr powder, and TiO₂ powder that are commonly used in the manufacture of sputtering targets are as follows.

Ru powder: Average particle diameter of more than 5 μm and less than 50 μm Co powder: Average particle diameter of more than 5 μm and less than 50 μm

Cr powder: Average particle diameter of more than 50 μm and less than 100 μm

TiO₂ powder: Average particle diameter of less than 1 μm

The hardness of a sputtering target having the same composition as that of Example 1, which was prepared in the same manner as Example 1 except that Ru powder, Co powder, Cr powder, and TiO₂ powder described in the preceding paragraph were used, was 907 by Vickers hardness HV10. Hereinafter this sputtering target referred to as a sputtering target of Reference Example 1.

Therefore, the hardness of the sputtering target of Example 1 (964 by Vickers hardness HV10) is improved by about 6% by Vickers hardness HV10 than the hardness of the sputtering target of Reference Example 1 (907 by Vickers hardness HV10), and the strength properties are improved.

The particle diameters of Ru powder, Co powder, Cr powder, Pt powder, and TiO₂ powder used in the preparation of the sputtering target (Ru₄₅Co₂₅Cr₂₅Pt₅-30 vol % TiO₂) of Example 28 are as follows.

Ru powder: Average particle diameter of less than 5 μm

Co powder: Average particle diameter of less than 5 μm

Cr powder: Average particle diameter of less than 50 μm

Pt powder: Average particle diameter of less than 5 μm

TiO₂ powder: Average particle diameter of less than 1 μm

The hardness of the obtained sputtering target was 926 by Vickers hardness HV10.

In contrast, the particle diameters of Ru powder, Co powder, Cr powder, Pt powder, and TiO₂ powder that are commonly used in the manufacture of sputtering targets are as follows.

Ru powder: Average particle diameter of more than 5 μm and less than 50 μm

Co powder: Average particle diameter of more than 5 μm and less than 50 μm

Cr powder: Average particle diameter of more than 50 μm and less than 100 μm Pt powder: Average particle diameter of more than 5 μm and less than 50 μm

TiO₂ powder: Average particle diameter of less than 5 μm

The hardness of a sputtering target having the same composition as that of Example 28, which was prepared in the same manner as Example 28 except that Ru powder, Co powder, Cr powder, Pt powder, and TiO₂ powder described in the preceding paragraph were used, was 893 by Vickers hardness HV10. Hereinafter this sputtering target referred to as a sputtering target of Reference Example 2.

Therefore, the hardness of the sputtering target of Example 28 (926 by Vickers hardness HV10) is improved by about 4% by Vickers hardness HV10 than the hardness of the sputtering target of Reference Example 2 (893 by Vickers hardness HV10), and the strength properties are improved.

The raw material metal powders used for preparing the sputtering targets in Examples 2 to 27 and 29 to 51 are also the metal powders having the same average particle diameter as the raw material metal powders used for preparing the sputtering targets of Examples 1 and 28, so that it is considered that the hardness of the sputtering targets of Examples 2 to 27 and 29 to 51 are about the same value as the hardness of the sputtering target of Examples 1 and 28, and it is considered that the hardness of the sputtering target of Examples 2 to 27 and 29 to 51 is 920 or more and 970 or less by Vickers hardness HV10.

### INDUSTRIAL APPLICABILITY

The sputtering target according to the present invention can be used for forming a buffer layer that enables the magnetic crystal grains in the magnetic recording layer granular film to be well separated each other when the magnetic recording layer granular film is stacked above a Ru underlayer, and has industrial applicability.

### REFERENCE SIGNS LIST

10, 50 magnetic recording medium
12, 52 Ru underlayer
buffer layer
14A alloy phase
14B Oxide Phase
16, 56 magnetic recording layer granular film
16A, 56A magnetic crystal grain
16B, 56B oxide phase

1. A sputtering target containing a metal and an oxide, wherein:
the contained metal becomes a nonmagnetic metal including an hcp structure if the entirety of the contained metal is made into a single metal, the lattice constant “a” of the hcp structure included in the nonmagnetic metal being 2.59 Å or more and 2.72 Å or less;
the contained metal includes 4 at % or more of metallic Ru relative to the whole amount of the contained metal;
the sputtering target contains 20 vol % or more and 50 vol % or less of the oxide relative to the entire sputtering target, the melting point of the contained oxide being 1700° C. or more; and
the hardness of the sputtering target is 926 or more by the Vickers hardness HV10.

2. The sputtering target according to claim 1, further containing: at least one metal selected from the group consisting of Nb, Ta, W, Ti, Pt, Mo, V, Mn, Fe, and Ni in a total amount of more than 0 at % and 31 at % or less relative to the whole amount of the metal contained in the sputtering target.

3. The sputtering target according to claim 1, further containing: at least one metal selected from the group consisting of Co and Cr in a total amount of more than 0 at % and less than 55 at % relative to the whole amount of the metal contained in the sputtering target.

4. The sputtering target according to claim 1, further containing: two or more metals selected from the group consisting of metallic Co, metallic Cr, and metallic Pt, wherein the metallic Ru is contained in an amount of 20 at % or more and less than 100 at %, the metallic Co is contained in an amount of 0 at % or more and less than 55 at %, the metallic Cr is contained in an amount of 0 at % or more and less than 55 at %, and the metallic Pt is contained in an amount of 0 at % or more and 31 at % or less relative to the whole amount of the metal contained in the sputtering target.

5. (canceled)

6. The sputtering target according to claim 1, wherein the oxide is an oxide of at least one element selected from the group consisting of Si, Ta, Co, Mn, Ti, Cr, Mg, Al, Y, Zr, and Hf.

7. The sputtering target according to claim 1, wherein the sputtering target is used for forming a buffer layer between a Ru underlayer and a magnetic recording layer.

8. The sputtering target according to claim 2, wherein the oxide is an oxide of at least one element selected from the group consisting of Si, Ta, Co, Mn, Ti, Cr, Mg, Al, Y, Zr, and Hf.

9. The sputtering target according to claim 3, wherein the oxide is an oxide of at least one element selected from the group consisting of Si, Ta, Co, Mn, Ti, Cr, Mg, Al, Y, Zr, and Hf.

10. The sputtering target according to claim 4, wherein the oxide is an oxide of at least one element selected from the group consisting of Si, Ta, Co, Mn, Ti, Cr, Mg, Al, Y, Zr, and Hf.

11. The sputtering target according to claim 2, wherein the sputtering target is used for forming a buffer layer between a Ru underlayer and a magnetic recording layer.

12. The sputtering target according to claim 3, wherein the sputtering target is used for forming a buffer layer between a Ru underlayer and a magnetic recording layer.

13. The sputtering target according to claim 4, wherein the sputtering target is used for forming a buffer layer between a Ru underlayer and a magnetic recording layer.

14. The sputtering target according to claim 6, wherein the sputtering target is used for forming a buffer layer between a Ru underlayer and a magnetic recording layer.

15. The sputtering target according to claim 8, wherein the sputtering target is used for forming a buffer layer between a Ru underlayer and a magnetic recording layer.

16. The sputtering target according to claim 9, wherein the sputtering target is used for forming a buffer layer between a Ru underlayer and a magnetic recording layer.

17. The sputtering target according to claim 10, wherein the sputtering target is used for forming a buffer layer between a Ru underlayer and a magnetic recording layer.
